(19) United States
(12) Patent Application Publication
(10) Pub. No.: US 2025/0275111 A1
(43) Pub. Date: Aug. 28, 2025

(54) SEMICONDUCTOR DEVICE

(71) Applicant: SAMSUNG ELECTRONICS CO., LTD., Suwon-si (KR)

(72) Inventors: Hoyoung Tang, Suwon-si (KR); Tae-Hyung Kim, Suwon-si (KR); Kiryong Kim, Suwon-si (KR); Bon-Yeop Kim, Suwon-si (KR); Jin-Myeong Hong, Suwon-si (KR)

(21) Appl. No.: 18/978,698

(22) Filed: Dec. 12, 2024

(30) Foreign Application Priority Data
Feb. 28, 2024 (KR) 10-2024-0028789
Mar. 19, 2024 (KR) 10-2024-0038038
Jun. 18, 2024 (KR) 10-2024-0079000

(51) Int. Cl. H10B 10/00

(52) U.S. Cl. CPC H10B 10/125; H10B 10/18

(57) ABSTRACT

The present disclosure relates to a semiconductor device which includes a cell region with a plurality of bit cells and a peripheral circuit region at one side of the cell region and in which a circuit controlling the plurality of bit cells is positioned. The semiconductor device includes a bitline in the cell region and the peripheral circuit region and a complementary bitline spaced apart from the bitline. Each of the plurality of bit cells includes two pull-up transistors, two pass transistors, and two pull-down transistors. The bitline includes a first portion positioned in the cell region and extending in a first direction, a second portion positioned in the peripheral circuit region and also extending in the first direction, and a third portion connecting the first portion to the second portion. The first portion to the third portion are formed integrally and positioned at the same layer.

### CROSS-REFERENCE TO RELATED APPLICATIONS

This application claims priority to and the benefit of Korean Patent Application No. 10-2024-0028789 filed in the Korean Intellectual Property Office on Feb. 28, 2024, of Korean Patent Application No. 10-2024-0038038 filed in the Korean Intellectual Property Office on Mar. 19, 2024, and of Korean Patent Application No. 10-2024-0079000 filed in the Korean Intellectual Property Office on Jun. 18, 2024, the entire contents of each of which is incorporated herein by reference.

### BACKGROUND

A memory device is a storage device capable of recording data and read it when needed. The memory device may include nonvolatile memory (NVM) in which stored data is not lost even when power is not supplied, and volatile memory (VM) in which stored data is lost when power is not supplied.

Meanwhile, as electronic devices such as electronic portable devices become smaller, the memory devices mounted on the electronic devices are also becoming smaller and lighter. As memory devices become smaller, various studies are being conducted to integrate more circuits within a limited space.

### SUMMARY

The present disclosure attempts to provide a semiconductor device capable of improving reliability.

A semiconductor device according to implementations includes a cell region where a plurality of bit cells are arranged, and a peripheral circuit region which is positioned at one side of the cell region and where a circuit controlling the plurality of bit cells is positioned, a bitline extended in a first direction in the cell region and the peripheral circuit region, and a complementary bitline spaced apart from the bitline in a second direction crossing the first direction, wherein each of the plurality of bit cells includes a first pull-up transistor pulling up a first storage node, a second pull-up transistor pulling up a second storage node, a first pass transistor connecting the first storage node to the bitline, a second pass transistor connecting the second storage node to the complementary bitline, a first pull-down transistor pulling down the first storage node, and a second pull-down transistor pulling down the second storage node, the bitlines includes a first portion positioned in the cell region and extended in the first direction, a second portion positioned in the peripheral circuit region and extended in the first direction, and a third portion connecting the first portion to the second portion, and the first portion to the third portion are formed integrally and positioned at the same layer.

A semiconductor device according to implementations includes a cell region where a plurality of bit cells are arranged, Da peripheral circuit region which is positioned at one side of the cell region and where a circuit controlling the plurality of bit cells is positioned, and a penetrating via structure positioned between the cell region and the peripheral circuit region, wherein the cell region includes gate lines positioned on a substrate and a cell bitline positioned on at a first wiring layer on the gate lines and extended in a first direction, each of the plurality of bit cells a first pull-up transistor pulling up a first storage node, a second pull-up transistor pulling up a second storage node, a first pass transistor connecting the first storage node to the bitline, a second pass transistor connecting the second storage node to the complementary bitline, a first pull-down transistor pulling down the first storage node, and a second pull-down transistor pulling down the second storage node, the peripheral circuit region includes a cell bitline extension wiring positioned at a second wiring layer below the substrate and extended in the first direction and a complementary cell bitline extension wiring positioned at the second wiring layer, extended in the first direction, and spaced apart from the cell bitline extension wiring in the second direction, and the penetrating via structure connects the cell bitline and the cell bitline extension wiring.

A semiconductor device according to implementations includes a cell region where a plurality of bit cells are arranged, and a peripheral circuit region which is positioned at one side of the cell region and where a circuit controlling the plurality of bit cells is positioned, a driving voltage line extended in a firs direction in the cell region, a bitline extended in the first direction and spaced apart from the driving voltage line in a second direction crossing the first direction, and a complementary bitline spaced apart from the bitline in the second direction in the cell region and the peripheral circuit region, wherein the bitlines includes a first portion positioned in the cell region and extended in the first direction, a second portion positioned in the peripheral circuit region and extended in the first direction, and a third portion connecting the first portion to the second portion, the first portion to the third portion are formed integrally and positioned at the same layer, and a width of the first portion along the second direction is greater than or equal to a width of the second portion along the second direction.

According to the implementations, the reliability of semiconductor devices may be improved.

### BRIEF DESCRIPTION OF THE DRAWINGS

FIG. 1 is a block diagram illustrating a semiconductor device according to implementations.

FIG. 2 is a layout diagram illustrating a semiconductor device according to implementations.

FIG. 3 is a block diagram illustrating a bit cell region, a dummy region, and a peripheral circuit region of a semiconductor device according to implementations.

FIG. 4 is a layout diagram illustrating a bit cell region, a dummy region, and a peripheral circuit region of a semiconductor device according to implementations.

FIG. 5 is an enlarged layout diagram of area Q1 of FIG. 4.

FIG. 6 is a circuit diagram for explaining a bit cell of a semiconductor device according to implementations.

FIG. 7 is a cross-sectional view illustrating a semiconductor device according to implementations.

FIG. 8 to FIG. 10 are layout diagrams illustrating bit cells of a semiconductor device according to implementations.

FIG. 11 is a layout diagram illustrating a bit cell region, a dummy region, and a peripheral circuit region of a semiconductor device according to some implementations.

FIG. 12 is a layout diagram illustrating a bit cell of a semiconductor device according to some implementations.

FIG. 13 and FIG. 14 are layout diagrams illustrating a bit cell region, a dummy region, and a peripheral circuit region of a semiconductor device according to some implementations.

FIG. 15 is a cross-sectional view along the A-A′ line in FIG. 14.

FIG. 16 is a cross-sectional view along the B-B′ line in FIG. 14.

FIG. 17 is a layout diagram illustrating a bit cell region, a dummy region, and a peripheral circuit region of a semiconductor device according to some implementations.

FIG. 18 is a cross-sectional view illustrating a standard cell of a semiconductor device according to implementations.

### DETAILED DESCRIPTION

Hereinafter, with reference to accompanying drawings, various implementations of the present disclosure will be described in detail so that a person of an ordinary skill can easily implement the present disclosure. The present disclosure may be implemented in many different forms and is not limited to the implementations described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown. In the drawings, the thickness of layers, films, panels, regions, etc., are exaggerated for clarity. And in the drawings, for convenience of explanation, the thicknesses of some layers and regions are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

In addition, throughout the specification, when referring to “a plane view”, it means that the target portion is viewed from above, and when referring to “a cross-section view”, it means that a cross section of the target portion cut vertically is viewed from a side.

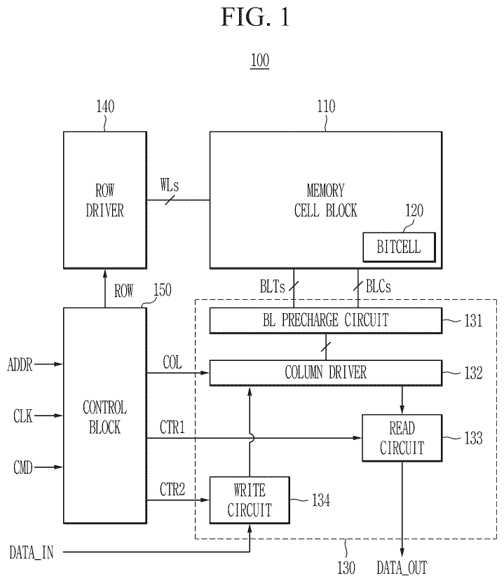

Hereinafter, a semiconductor device according to some implementations will be described, referring to FIG. 1.

Referring to FIG. 1, the semiconductor device 100 according to some implementations may be a memory device. For example, a semiconductor device 100 according to some implementations may store data by a plurality of bit cells 120, each of which is accessed by a gate signal line and a bitline. In implementations, the plurality of bit cells 120 may be volatile memory cells, such as static random access memory (SRAM), dynamic random access memory (DRAM), etc. As another example, the plurality of bit cells 120 may be non-volatile memory cells, such as flash memory, RRAM (resistive random access memory), etc. Implementations of the present disclosure will be described primarily with reference to SRAM cells but are not limited thereto.

A semiconductor device 100 may receive a command CMD, address ADDR, clock CLK, and write-in data DATA_IN, and output read-out data DATA_OUT. For example, the semiconductor device 100 may receive a command CMD instructing writing (which may be referred to as a write-in command), an address (which may be referred to as a write-in address), and the write-in data DATA_IN, and may store the write-in data DATA_IN in a region of a memory cell block 110 corresponding to the address. In addition, the semiconductor device 100 may receive a command CMD instructing reading (which may be referred to as a read-out command) and an address (which may be referred to as a read-out address) and may output read-out data DATA_OUT stored in a region of a memory cell block 110 corresponding to the address to the outside.

The semiconductor device 100 according to some implementations may include a memory cell block 110, an input/output block 130, a row driver 140, and a control block 150.

The memory cell block 110 may include a plurality of bit cells 120. Each of the plurality of bit cells 120 may be connected to one of the plurality of gate signal lines WLs, and may be connected to at least one of a plurality of bitlines BLTs, and to at least one of a plurality of complementary bitlines BLCs.

The row driver 140 may be connected to the memory cell block 110 through the plurality of gate signal lines WLs. The row driver 140 may activate one of the plurality of gate signal lines WLs based on a row address ROW. Accordingly, among the plurality of memory cells, memory cells connected to the activated gate signal line may be selected. That is, the row driver 140 may select any one of a plurality of gate signal lines WLs.

The control block 150 may receive a command CMD, an address ADDR, and a clock CLK, and may generate a row address ROW, a column address COL, a first control signal CTR1, and a second control signal CTR2. (For example, the control block 150 may identify a read-out command by decoding the command CMD, and may generate a row address ROW, a column address COL, and a first control signal CTR1 to read the read-out data DATA_OUT from memory cell block 110. Also, the control block 150 may identify a write-in command by decoding the command CMD, and may generate a row address ROW, a column address COL, and a second control signal CTR2 to write data DATA_IN to the memory cell block 110.

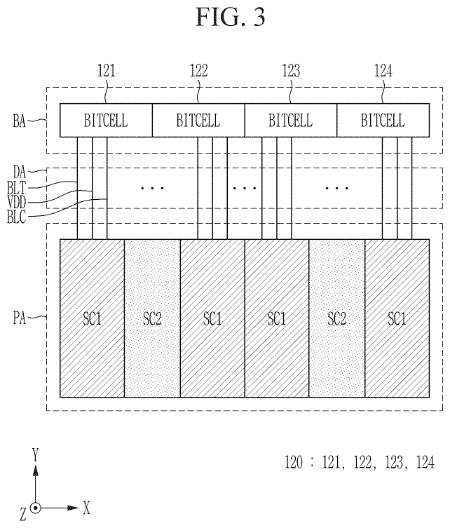

The input/output block 130 may be connected to the memory cell block 110 through a plurality of bitlines BLTs and a plurality of complementary bitlines BLCs. In implementations, the plurality of complementary bitlines BLCs may be complementary to the plurality of bitlines BLTs. The input/output block 130 may be connected to each of a plurality of bit cells 120 through a pair of bitlines (BLT in FIG. 3) and complementary bitlines (BLC in FIG. 3). A detailed description for this will be given later with reference to FIG. 3 to FIG. 5.

The input/output block 130 may include a bitline precharge circuit 131, a column driver 132, a read-out circuit 133, and a write-in circuit 134.

The bitline precharge circuit 131 may be connected to the memory cell block 110 through the plurality of bitlines BLTs and the plurality of complementary bitlines BLCs. The bitline precharge circuit 131 may precharge the plurality of bitlines BLTs and the plurality of complementary bitlines BLCs. For example, bitline precharge circuit 131 may be connected to bit cell 120 of memory cell block 110 through a pair of a bitline (BLT of FIG. 3) and a complementary bitline (BLC of FIG. 3).

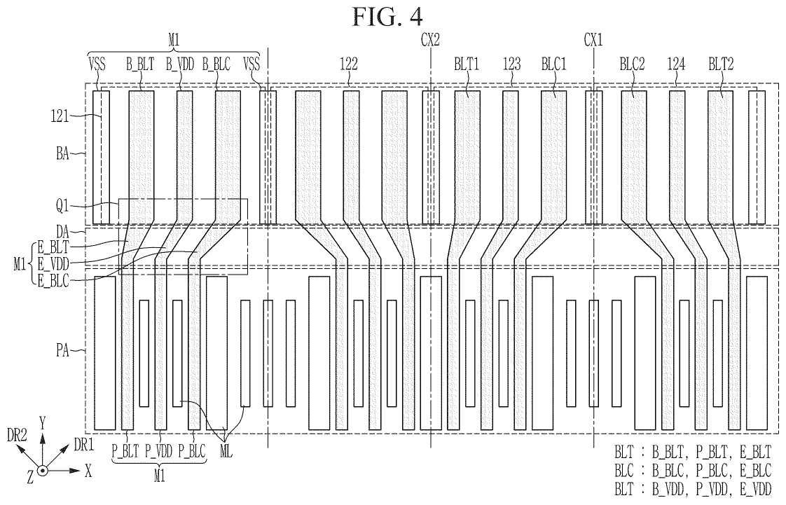

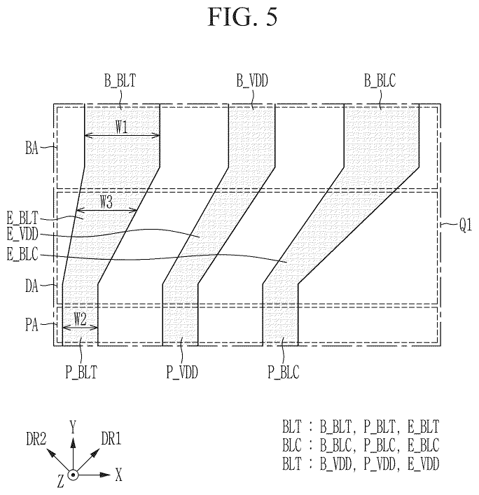

The column driver 132 may be connected to bitline precharge circuit 131. The column driver 132 may be connected to bitline precharge circuit 131 through the plurality of bitlines BLTs and the plurality of complementary bitlines BLCs. The column driver 132 may select a pair of a bitline (BLT in FIG. 3) and a complementary bitline (BLC in FIG. 3) based on the column address COL. As selecting a pair of a bitline (BLT of FIG. 3) and a complementary bitline (BLC of FIG. 3), a bit cell 120 connected to the selected bitlines 120 may be selected from the plurality of bit cells. At this time, the bitline BLT and the complementary bitline BLC may be connected to both ends of the bit cell 120 of memory cell block 110, respectively. The relationship between the bit cell 120 and bitline BLT and complementary bitline BLC will be described later in FIG. 4 and FIG. 5.

The read-out circuit 133 may receive a first control signal CTR1 from the control block 150. The read-out circuit 133 may perform a read-out operation based on the first control signal CTR1. Specifically, the read circuit 133 may identify a value stored in a selected bit cell 120 (i.e., a bit cell 120 connected to an activated gate signal line) by detecting current and/or voltage received through a plurality of bitlines BLTs and a plurality of complementary bitlines BLCs during a read operation and may output read-out data DATA_OUT based on the identified value. The read-out circuit 133 may be connected to the column driver 132. The read-out circuit 133 may include a sense amplifier but is not limited thereto.

The write-in circuit 134 may receive a second control signal CTR2 from the control block 150. The write-in circuit 134 may perform a write-in operation based on the second control signal CTR2. Specifically, the write-in circuit 134 may apply current and/or voltage to the plurality of bitlines BLTs and the plurality of complementary bitlines BLCs based on write-in data DATA_IN during a write operation and may write a value to a selected bit cell 120 (i.e., a bit cell 120 connected to an activated gate signal line). The write-in circuit 134 may be connected to the column driver 132. Here, at least one bitline may include a bitline BLT and a complementary bitline BLC.

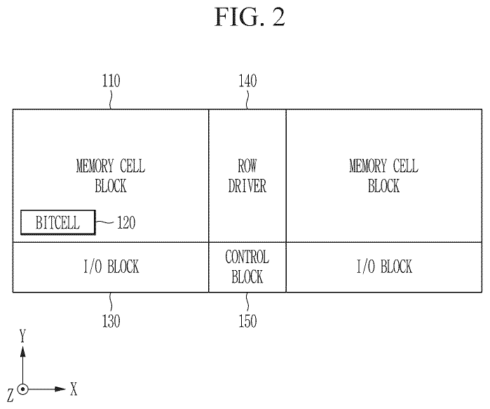

Hereinafter, referring to FIG. 2, a semiconductor device according to some implementations will be described.

FIG. 2 is a layout diagram illustrating a semiconductor device according to implementations.

For example, the plane view of FIG. 2 illustrates a layout corresponding to semiconductor device 100 of FIG. 1.

Referring to FIG. 2, the row driver 140 may be positioned adjacent to the memory cell block 110 in the first direction (X direction). The row driver 140 may be positioned between memory cell blocks 110 adjacent to each other in the first direction (X direction). The row driver 140 may access bit cell 120 through the gate signal line.

The input/output block 130 may be positioned adjacent to the memory cell block 110 in a second direction (Y direction) intersecting the first direction (X direction). The input/output block 130 may perform write-in or read-out operations.

The control block 150 may be positioned adjacent to the input/output block 130 in the first direction (X direction) and adjacent to the row driver 140 in the second direction (Y direction). The control block 150 may be positioned between input/output blocks 130 adjacent in the first direction (X direction). The control block 150 may transmit signals to perform write-in or read-out operations. Hereinafter, the input/output block 130, the row driver 140, and the control block 150, except the memory cell block 110 of the semiconductor device 100, may be referred to as a peripheral circuit.

Hereinafter, a semiconductor device according to some implementations will be described with reference to FIG. 3.

FIG. 3 is a block diagram illustrating a bit cell region, a dummy region, and a peripheral circuit region of a semiconductor device according to implementations.

Referring to FIG. 3, a semiconductor device according to some implementations may include a cell region BA and a peripheral circuit region PA. The cell region BA may mean a region where the memory cell block 110 of the implementations of FIG. 2 is positioned, and the peripheral circuit region PA may mean a region where at least a part of the peripheral circuit of the implementations of FIG. 2 is positioned. For example, the input/output block 130 may be positioned in the peripheral circuit region PA. However, the position is not limited thereto, as another example, the row driver 140 and/or the control block 150 may positioned in the peripheral circuit region PA.

A plurality of bit cells 120 may be positioned in the cell region BA. The plurality of bit cells 120 may be arranged adjacently in the first direction (X direction). For example, first to fourth bit cells 121, 122, 123, 124 may be arranged along the first direction (X direction), but are not limited thereto. Each of the first to fourth bit cells 121, 122, 123, 124 may be electrically connected to standard cells (e.g., standard cells implementing circuits constituting the input/output block 130 of FIG. 1 and FIG. 2) positioned in the peripheral circuit region PA, through the bitlines BLT and complementary bitlines BLC.

The peripheral circuit region PA may be positioned at one side of the cell region BA. For example, the peripheral circuit region PA may be positioned at one side of the cell region BA along the second direction (Y direction), but is not limited thereto.

A plurality of standard cells SC1 and SC2 may be positioned in the peripheral circuit region PA. The plurality of standard cells SC1 and SC2 may be arranged in the first direction (X direction). The plurality of standard cells SC1 and SC2 may be cells forming at least a part of the peripheral circuit according to implementations. The plurality of standard cells SC1 and SC2, as a unit of layout, may refer to a region designed to perform a predefined function. For example, the plurality of standard cells SC1 and SC2 positioned at one side of memory cell block 110 may form the input/output block 130 of the implementations of FIG. 1 and FIG. 2. As another example, the plurality of standard cells SC1 and SC2 positioned at one side of memory cell block 110 may form the row driver 140 or the control block 150 of implementations of FIG. 1 and FIG. 2. The plurality of standard cells SC1 and SC2 may be designed as CMOS transistors including P-type transistors and N-type transistors. For example, the first standard cell SC1 may consist of a P-type transistor, and the second standard cell SC2 may consist of an N-type transistor. The plurality of standard cells SC1 and SC2 may implement a peripheral circuit that writes data to a plurality of bit cells 120 or reads data from a plurality of bit cells 120.

In implementations, the plurality of bit cells 120 may correspond to the plurality of standard cells SC1 and SC2. For example, as illustrated in FIG. 3, four bit cells 121, 122, 123, 124 may correspond to six standard cells SC1 and SC2, but the ratio of bit cells to standard cells is not limited thereto and may be modified in various manners.

In implementations, the plurality of standard cells SC1 and SC2 may write data to a plurality of bit cells 120 or read data from a plurality of bit cells 120. Each of the plurality of bit cells 120 may be electrically connected to the plurality of standard cells SC1 and SC2 through the bitline BLT and the complementary bitline BLC. Accordingly, a signal for writing data or a signal for reading data may be applied to the plurality of bit cells 120 through the bitline BLT and the complementary bitline BLC. Additionally, each of the plurality of bit cells 120 may be electrically connected to the plurality of standard cells SC1 and SC2 through a driving voltage line VDD. A driving voltage may be applied to each of the plurality of bit cells 120 through the driving voltage line VDD. The arrangement and shape of bitline BLT, complementary bitline BLC and driving voltage line VDD will be described later with reference to FIG. 4.

A semiconductor device according to some implementations may further include a dummy region DA positioned between the cell region BA and the peripheral circuit region PA.

A dummy region DA may be a region electrically connecting between the plurality of bit cells 120 and the plurality of standard cells SC1 and SC2. In the dummy region DA, a plurality of wirings (e.g., bitline BLT, complementary bitline BLC, and driving voltage line VDD) connecting between the plurality of bit cells 120 and the plurality of standard cells SC1 and SC2 may be positioned. In some implementations, a dummy cell may be positioned in the dummy region DA but is not limited thereto.

Hereinafter, the arrangement and shape of the bitlines, complementary bitlines, and driving voltage lines of a semiconductor device according to some implementations will be described with reference to FIG. 4 and FIG. 5.

FIG. 4 is a layout diagram illustrating a bit cell region, a dummy region, and a peripheral circuit region of a semiconductor device according to implementations. FIG. 5 is an enlarged layout diagram of area Q1 of FIG. 4.

In FIG. 4, only the arrangement and shape of the cell region BA, peripheral circuit region PA, dummy region D, bitline BLT, complementary bitline BLC, and driving voltage line VDD which connect between plurality of bit cells 120 and plurality of standard cells SC1 and SC2 are shown for better understanding and convenience of description. In FIG. 5, only the bitline BLT, complementary bitline BLC and driving voltage line VDD are shown for better understanding and ease of description. Hereinafter, the bitline BLT, the complementary bitline BLC and the driving voltage line VDD will be described with reference to FIG. 4 and FIG. 5.

Referring to FIG. 4, a semiconductor device according to some implementations may include a bitline BLT and a complementary bitline BLC positioned in a cell region BA, a dummy region DA, and a peripheral circuit region PA.

The bitline BLT and the complementary bitline BLC may be extended from the cell region BA through the dummy region DA to the peripheral circuit region PA. The bitlines BLT and the complementary bitlines BLC may be positioned at the same layer across the cell region BA, dummy region DA, and peripheral circuit region PA. For example, the bitline BLT and the complementary bitline BLC may be positioned on the plurality of bit cells 120 across a cell region BA, a dummy region DA, and a peripheral circuit region PA but are not limited thereto.

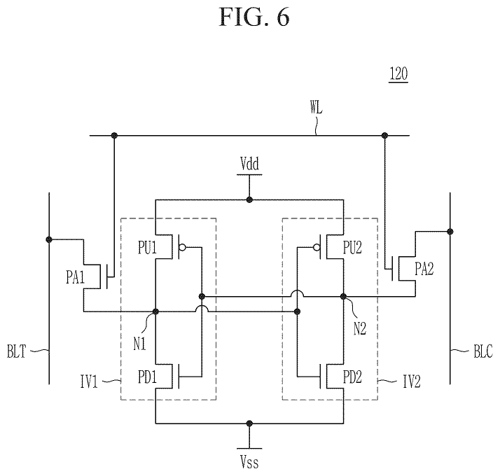

The bitline BLT and the complementary bitline BLC may be electrically connected to the plurality of bit cells 120. The bitline BLT and the complementary bitline BLC may be electrically connected to a plurality of standard cells (SC1 and SC2 in FIG. 3) of the peripheral circuit region PA. In other words, the plurality of standard cells (SC1 and SC2 in FIG. 3) and the plurality of bit cells 120 may be electrically connected through bitlines BLT and complementary bitlines BLC. A signal for writing data or a signal for reading data may be applied to the plurality of bit cells 120 through the bitline BLT and the complementary bitline BLC. Further explanation of this will be described later with reference to FIG. 6.

In implementations, the bitline BLT and the complementary bitline BLC may be extended approximately in the second direction (Y direction). The bitline BLT and complementary bitline BLC may be positioned apart from each other along the first direction (X direction). The bitlines BLT and complementary bitlines BLC may be arranged along the first direction (X direction). For example, the bitlines BLT and complementary bitlines BLC may be arranged alternately along the first direction (X direction). For example, as illustrated in FIG. 4, the first bitline BLT1 and the first complementary bitline BLC1 which are connected to the third bit cell 123, and the second complementary bitline BLC2 and the second bitline BLT2 which are connected to the fourth bit cell 124 may be arranged to be sequentially spaced apart from each other along the first direction (X direction). That is, the first complementary bitline BLC1 may be positioned between the first bitline BLT1 and the second bitline BLT2, and the second complementary bitline BLC2 may be positioned between the first complementary bitline BLC1 and the second bitline BLT2. Here, the first bitline BLT1 and the second bitline BLT2 may be referred to as bitlines connected to one of bit cells 120. Also, the first complementary bitline BLC1 and the second complementary bitline BLC2 may be referred to as complementary bitlines connected to one of bit cells 120.

At this time, bitlines BLT adjacent in the first direction (X direction) and complementary bitlines BLC adjacent in the first direction (X direction) may have a shape symmetrical to each other. For example, the first bitline BLT1 and the second bitline BLT2 may have a shape symmetrical to each other with respect to a first reference axis CX1 between the third bit cell 123 and the fourth bit cell 124. Here, the first reference axis CX1 may mean an extension of a boundary between the third bit cell 123 and the fourth bit cell 124, which is extended in the second direction (Y direction). Also, the first complementary bitline BLC1 and the second complementary bitline BLC2 may have shapes symmetrical to each other with respect to the first reference axis CX1. Such shapes of the first bitline BLT1, the first complementary bitline BLC1, the second complementary bitline BLC2, and the second bitline BLT2 may be arranged repeatedly along the first direction (X direction).

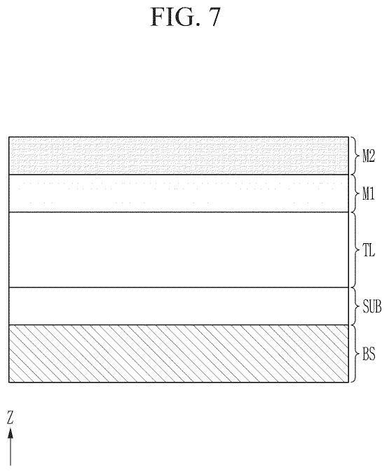

Accordingly, a bitline BLT connected to the second bit cell 122 adjacent to the third bit cell 123 may have a shape symmetrical to the first bitline BLT1 with respect to a second reference axis CX2 between the third bit cell 123 and the second bit cell 122. A complementary bitline BLC connected to the second bit cell 122 may have a shape symmetrical to the first complementary bitline BLC1 with respect to the second reference axis CX2. Here, the second reference axis CX2 may mean an extension of a boundary between the second bit cell 122 and the third bit cell 123, which is extended in the second direction (Y direction). In implementations, the bitline BLT may be positioned on the plurality of bit cells 120. For example, the bitline BLT may be positioned at the first wiring layer (M1 in FIG. 7) on the plurality of bit cells 120 but is not limited thereto.

Referring to FIG. 5, the bitline BLT may include a first portion B_BLT positioned in the cell region BA, a second portion P_BLT positioned in the peripheral circuit region PA, and a third portion E_BLT connecting between the first portion B_BLT and the second portion P_BLT.

In implementations, the first portion B_BLT to the third portion E_BLT of a bitline BLT may be positioned at the same layer. For example, the first portion B_BLT to the third portion E_BLT may be positioned at the first wiring layer (M1 of FIG. 7) positioned on a plurality of bit cells 120. In implementations, the first portion B_BLT to the third portion E_BLT may be formed integrally. The first portion B_BLT to the third portion E_BLT may be integrally formed in the same process.

The first portion B_BLT may be extended in the second direction (Y direction) from the cell region BA. The second portion P_BLT may be extended in the same direction as the first portion B_BLT. The first portion B_BLT may overlap a plurality of bit cells 120 in a third direction (Z direction). The first portion B_BLT may mean the bitline BLT portion positioned in the cell region BA.

The second portion P_BLT may be extended in the second direction (Y direction) from the peripheral circuit region PA. The second portion P_BLT may refer to a bitline BLT portion positioned in the peripheral circuit region PA. The second portion P_BLT may not be aligned with the first portion B_BLT in the second direction (Y direction), but is not limited thereto. The third portion E_BLT may be positioned in the dummy region DA. In implementations, the first width W1 of the first portion B_BLT along the first direction (X direction) may be greater than or equal to the second width W2 of the second portion P_BLT along the first direction (X direction). This may be due to device characteristics that space for forming bitlines (BLTs) in the peripheral circuit region PA is insufficient since the number of plurality of standard cells (SC1, SC2 in FIG. 3) is greater than the number of plurality of bit cells 120 positioned within a region having the same width, and the number of wirings per unit area positioned within the peripheral circuit region PA is greater than the number of wirings per unit area positioned within the cell region BA. For example, in the peripheral circuit region PA, separate wirings ML for driving a plurality of standard cells (SC1, SC2 of FIG. 3) of the peripheral circuit region PA may be further positioned.

The third portion E_BLT may connect between the first portion B_BLT and the second portion P_BLT. The third portion E_BLT may be extended in a first diagonal direction DR1 intersecting the first direction (X direction) and the second direction (Y direction). The third portion E_BLT may refer to the bitline BLT portion positioned between the first portion B_BLT and the second portion P_BLT. The third portion E_BLT may be positioned in the dummy region DA, but is not limited thereto. In implementations, the third width W3 of the fifth portion P_BLC along the first direction (X direction) may gradually decrease as the distance from the first portion B_BLT increases. The maximum width of the third portion E_BLT along the first direction (X direction) may be substantially the same as the first width W1 of the first portion B_BLT along the first direction (X direction), and the minimum width of the third portion E_BLT along the first direction (X direction) may be substantially the same as the second width W2 of the second portion P_BLT along the first direction (X direction).

In implementations, since the first portion B_BLT and the second portion P_BLT are not aligned in the second direction (Y direction), the third portion E_BLT may be extended in the first diagonal direction DR1. Accordingly, in implementations, the bitline BLT may have a bent portion between the first portion B_BLT and the second portion P_BLT and between the second portion P_BLT and the third portion E_BLT.

The complementary bitline BLC may include a fourth portion B_BLC positioned in a cell region BA, a fifth portion P_BLC positioned in a peripheral circuit region PA, and a sixth portion E_BLC connecting between the fourth portion B_BLC and the fifth portion P_BLC.

In implementations, the fourth portion B_BLC to the sixth portion E_BLC of a complementary bitline BLC may be positioned at the same layer. The fourth portion B_BLC to the sixth portion E_BLC may be positioned at the same layer as the first portion B_BLT to the third portion E_BLT of the bitline BLT. For example, the fourth portion B_BLC to the sixth portion E_BLC may be positioned at the first wiring layer (M1 of FIG. 7) positioned on a plurality of bit cells 120. In implementations, the fourth portion B_BLC to the sixth portion E_BLC may be formed integrally. The fourth portion B_BLC to the sixth portion E_BLC may be integrally formed in the same process.

The fourth portion B_BLC may be extended in the second direction (Y direction) from the cell region BA. The fifth portion P_BLC may be extended in the same direction as the fourth portion B_BLC. The fourth portion B_BLC may overlap a plurality of bit cells 120 in the third direction (Z direction). The width of the fourth portion B_BLC along the first direction (X direction) may be substantially the same as the first width W1 of the first portion B_BLT along the first direction (X direction). The fourth portion B_BLC may refer to a complementary bitline BLC portion positioned in the cell region BA.

The fifth portion P_BLC may be extended in the second direction (Y direction) from the peripheral circuit region PA. The fifth portion P_BLC may refer to a complementary bitline BLC portion positioned in the peripheral circuit region PA. The fifth portion P_BLC may not be aligned with the fourth portion B_BLC in the second direction (Y direction), but is not limited thereto. The sixth portion E_BLC may be positioned in the dummy region DA. In implementations, the width of the fifth portion P_BLC along the first direction (X direction) may be substantially the same as the second width W2 of the second portion P_BLT along the first direction (X direction). In implementations, the width of the fourth portion B_BLC along the first direction (X direction) may be greater than or equal to the width of the fifth portion P_BLC along the first direction (X direction). This may be due to device characteristics that space for forming complementary bitlines BLC in the peripheral circuit region PA is insufficient since the number of plurality of standard cells SC1, SC2 is greater than the number of plurality of bit cells 120 positioned within a region having the same width, and the number of wirings per unit area positioned within the peripheral circuit region PA is greater than the number of wirings per unit area positioned within the cell region BA.

The sixth portion E_BLC may connect between the fourth portion B_BLC and the fifth portion P_BLC. The sixth portion E_BLC may be extended in the first diagonal direction DR1, which intersects the first direction (X direction) and the second direction (Y direction). The sixth portion E_BLC may refer to a complementary bitline BLC portion positioned between the fourth portion B_BLC and the fifth portion P_BLC. The sixth portion E_BLC may be positioned in the dummy region DA, but is not limited thereto. In implementations, the width the sixth portion E_BLC along the first direction (X direction) may gradually decrease as the distance from the fourth portion B_BLC increases. The maximum width of the sixth portion E_BLC along the first direction (X direction) may be substantially the same as the width of the fourth portion B_BLC along the first direction (X direction), and the minimum width of the sixth portion E_BLC along the first direction (X direction) may be substantially the same as the width of the fifth portion P_BLC along the first direction (X direction).

Again referring to FIG. 4, the semiconductor device according to implementations may further include a driving voltage line VDD space apart from the bitline BLT in the first direction (X direction).

The driving voltage line VDD may be positioned at the same layer as the bitline BLT and complementary bitline BLC. For example, the driving voltage line VDD may be positioned at the first wiring layer (M1 in FIG. 7) positioned on the plurality of bit cells 120, but is not limited thereto.

In implementations, the driving voltage line VDD may be positioned on the cell region BA, the dummy region DA, and the peripheral circuit region PA. The driving voltage line VDD may be extended approximately in the second direction (Y direction). The driving voltage line VDD may be extended from the cell region BA through the dummy region DA to the peripheral circuit region PA. The driving voltage lines may be positioned apart from each other along the first direction (X direction). For example, the driving voltage line VDD may be positioned between the bitline BLT and the complementary bitline BLC. The driving voltage line VDD may electrically connect between the plurality of bit cells 120 and the plurality of standard cells (SC1, SC2 in FIG. 3) of peripheral circuit regions PAs. The driving voltage line VDD may apply driving voltages to the plurality of bit cells 120. Further explanation of this will be described later with reference to FIG. 6.

The driving voltage line VDD may include a seventh portion B_VDD positioned in the cell region BA, an eighth portion P_VDD positioned in the peripheral circuit region PA, and a ninth portion E_VDD connecting between the seventh portion B_VDD and the eighth portion P_VDD.

In implementations, the seventh portion B_VDD to the ninth portion E_VDD may be positioned at the same layer. For example, the seventh portion B_VDD to the ninth portion E_VDD may be positioned at the first wiring layer (M1 of FIG. 7) positioned on a plurality of bit cells 120. In implementations, the seventh portion B_VDD to the ninth portion E_VDD may be formed integrally. The seventh portion B_VDD to the ninth portion E_VDD may be integrally formed in the same process.

The seventh portion B_VDD may be extended in the second direction (Y direction) from the cell region BA. The eighth portion P_VDD may be extended in the second direction (Y direction) from the peripheral circuit region PA. The ninth portion E_VDD may be connected between the seventh portion B_VDD and the eighth portion P_VDD. The ninth portion E_VDD may be extended in the first diagonal direction DR1 intersecting the first direction (X direction) and the second direction (Y direction). The ninth portion E_VDD may refer to the driving voltage line VDD portion positioned between the seventh portion B_VDD and the eighth portion P_VDD. The remaining description of the seventh portion B_VDD to the ninth portion E_VDD is substantially the same as the description of the fourth portion B_BLC to the sixth portion E_BLC of the complementary bitline BLC, so it will be omitted.

The semiconductor device according to some implementations may further include a ground voltage line VSS spaced apart from the bitline BLT in the first direction (X direction).

The ground voltage line VSS may be extended in the second direction (Y direction). The ground voltage line VSS may be spaced apart from the bitline BLT, complementary bitline BLC, and driving voltage line VDD in the first direction (Y direction). In implementations, the ground voltage line VSS may be positioned at the same layer as the bitline BLT and the complementary bitline BLC. For example, the ground voltage line VSS may be positioned at the first wiring layer (M1 in FIG. 7) positioned on the plurality of bit cells 120 but is not limited thereto.

In a semiconductor device according to implementations, the bitlines BLT and the complementary bitlines BLC may be positioned at the same layer across a cell region BA and a peripheral circuit region PA and may be formed integrally. In other words, each of the bitline BLT portion and the complementary bitline BLC portion positioned in the cell region BA may be directly connected to the bitline BLT portion and the complementary bitline BLC portion positioned in the peripheral circuit region PA without other connection wiring and contacts positioned at different layers. Accordingly, the resistance component by separate connection wiring and the resistance component by contact may be removed, and the total resistance of the bitline BLT and complementary bitline BLC may be reduced. Therefore, the reliability of the signal applied to bit cell 120 from the peripheral circuit through the bitline BLT and complementary bitline BLC may be improved, and the reliability of the semiconductor device can be improved.

Hereinafter, the bit cell of a semiconductor device according to some implementations will be described with reference to FIG. 6.

FIG. 6 is a circuit diagram for explaining a bit cell of a semiconductor device according to implementations. The bit cell 120 of embodiment of FIG. 6 may mean the plurality of bit cells 120 of implementations of FIG. 1 to FIG. 4. Here, the bit cell 120 may be a cell constituting SRAM but is not limited thereto.

Referring to FIG. 6, the bit cell 120 may include a first pull-up transistor PU1, a first pull-down transistor PD1, a second pull-up transistor PU2, a second pull-down transistor PD2, a first pass transistor PA1, and a second pass transistor PA2. The first pull-up transistor PU1 and the second pull-up transistor PU2 may be P-type transistors, and the first pull-down transistor PD1, the second pull-down transistor PD2, the first pass transistor PA1 and the second pass transistor PA2 may be N-type transistors but are not limited thereto.

The first pull-up transistor PU1 and the first pull-down transistor PD1 may form a first inverter IV1. The gates of the first pull-up transistor PU1 and the first pull-down transistor PD1 may be connected to each other. The connected gates of the first pull-up transistor PU1 and the first pull-down transistor PD1 may correspond to an input terminal of the first inverter IV1. The first storage node N1 may correspond to the output terminal of the first inverter IV1. The first pull-up transistor PU1 may pull up the first storage node N1.

The second pull-up transistor PU2 and the second pull-down transistor PD2 may form a second inverter IV2. The gates of the second pull-up transistor PU2 and the second pull-down transistor PD2 may be connected to each other. The connected gates of the second pull-up transistor PU2 and the second pull-down transistor PD2 may correspond to the input terminal of the second inverter IV2. The second storage node N2 may correspond to the output terminal of the second inverter IV2. The second pull-up transistor PU2 may pull up the second storage node N2.

The first inverter IV1 and the second inverter IV2 may be combined to form a latch structure. The gates of the first pull-up transistor PU1 and the first pull-down transistor PD1 may be electrically connected to the second storage node N2, and the gates of the second pull-up transistor PU2 and the second pull-down transistor PD2 may be electrically connected to the first storage node N1. In other words, the input terminal of the first inverter IV1 may be connected to the output terminal of the second inverter IV2, and the input terminal of the second inverter IV2 may be connected to the output terminal of the first inverter IV1.

The source and drain of the first pass transistor PA1 may be connected to the first storage node N1 and bitline BLT, respectively. The first pass transistor PA1 may be gated by the gate signal line WL to connect the first storage node N1 to the bitline BLT. The source and drain of the second pass transistor PA2 may be connected to the second storage node N2 and the complementary bitline BLC, respectively. The second pass transistor PA2 may be gated by the gate signal line WL to connect the second storage node N2 to the complementary bitline BLC. At this time, bitline BLT may be complementary to the complementary bitline BLC. That is, a signal applied to a bitline BLT may have a relationship complementary to a signal applied to a complementary bitline BLC. The gates of the first pass transistor PA1 and the second pass transistor PA2 may be electrically connected to the gate signal line WL.

The first storage node N1 and the second storage node N2 may store data of the bit cells 120. Data stored in the first storage node N1 and data stored in the second storage node N2 may have a relationship complementary to each other. Specifically, when the voltage level of the first storage node N1 is a high level, the voltage level of the second storage node N2 may be a low level. Conversely, when the voltage level of the first storage node N1 is a low level, the voltage level of the second storage node N2 may be a high level.

In the bit cell 120, the first pass transistor PA1 and the second pass transistor PA2 may be turned on when the voltage of the gate signal line WL becomes a first level (e.g., logic high). Accordingly, a signal of bitline BLT may be applied to the first storage node N1, and a signal of complementary bitline BLC may be applied to the second storage node N2. Data may be stored in the first storage node N1 and the second storage node N2 according to the signal of the bitline BLT and the signal of the complementary bitline BLC. Also, data stored in the first storage node N1 and the second storage node N2 may be read out according to the signal of the bitline BLT and the signal of the complementary bitline BLC.

Hereinafter, a semiconductor device according to some implementations will be described with reference to FIG. 7.

FIG. 7 is a cross-sectional view illustrating a semiconductor device according to implementations. FIG. 7 illustrates a plurality of layers constituting a semiconductor device according to implementations.

Referring to FIG. 7, a semiconductor device according to some implementations may include a substrate SUB, a device layer TL positioned on the substrate SUB, a first wiring layer M1 positioned on the device layer TL, and a second wiring layer BS positioned below the substrate SUB.

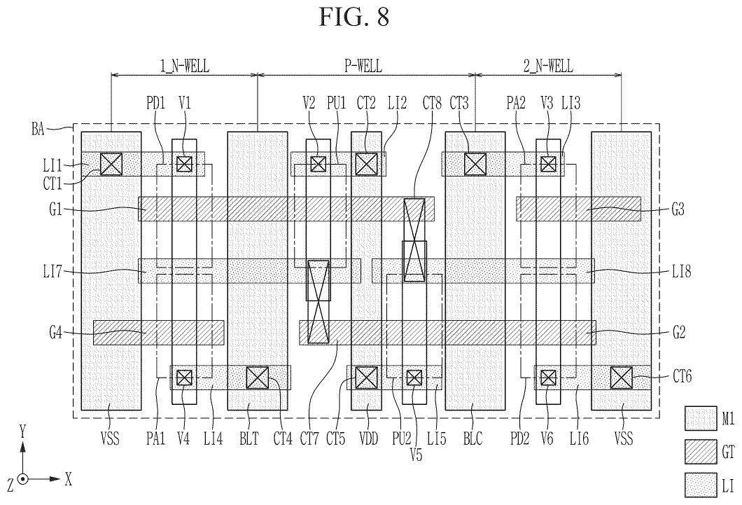

The device layer TL may be positioned on the substrate SUB. Various wirings and/or patterns forming the transistors of a bit cell 120 according to some implementations may be positioned at the device layer TL. For example, at the device layer TL, gate lines (G1-G4 in FIG. 8), local interconnects (LI1-LI8 in FIG. 8) connected to the gate lines (G1-G4 in FIG. 8), channel patterns, source/drain patterns, contact electrodes connected to the source/drain patterns, and the like may be positioned.

The first wiring layer M1 may be positioned as the device layer TL. That is, the first wiring layer M1 may be positioned on the top surface of the substrate SUB. The first wiring layer M1 may be positioned on the gate lines (G1-G4 in FIG. 8). At the first wiring layer M1, various wirings connected to the transistors of the semiconductor device may be positioned. For example, at least one of a bitline BLT, a complementary bitline BLC, a driving voltage line VDD, and a ground voltage line VSS of a semiconductor device according to some implementations may be positioned at the first wiring layer M1. In implementations, the bitline BLT, the complementary bitline BLC, the driving voltage line VDD, and the ground voltage line VSS may be positioned at the first wiring layer M1. That is, the bitline BLT, the complementary bitline BLC, the driving voltage line VDD, and the ground voltage line VSS may be positioned on bit cell 120. In some implementations, an insulating layer may be further positioned between the first wiring layer M1 and the device layer TL.

The second wiring layer BS may be positioned on a bottom surface of the substrate SUB. At the second wiring layer BS, various wirings connected to the transistors of the semiconductor device may be positioned. For example, a gate signal line WL may be positioned at the second wiring layer BS. However, the positions are not limited thereto, at least one of a bitline BLT, a complementary bitline BLC, a driving voltage line VDD, and a ground voltage line VSS may be positioned at the second wiring layer BS depending on implementations.

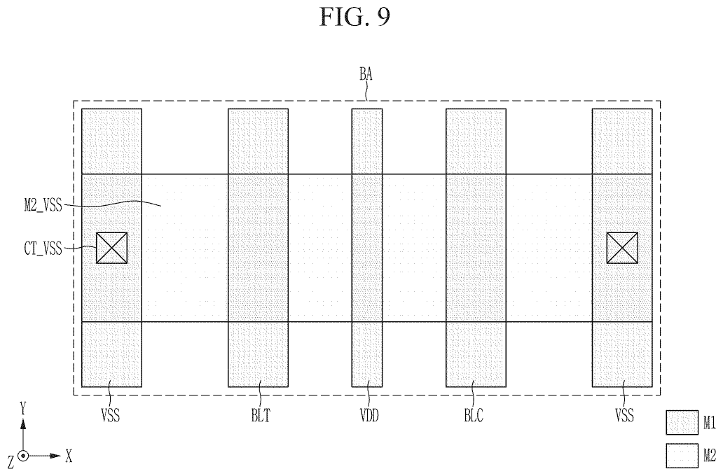

A semiconductor device according to some implementations may further include a third wiring layer M2 positioned on the first wiring layer M1. At the third wiring layer M2, various wirings connected to the first wiring layer M1 may be positioned. In implementations, a sub-ground voltage (M2_VSS of FIG. 9) connected to the ground voltage line VSS may be positioned at the third wiring layer M2. However, implementations are not limited thereto and wirings connected to at least one of the bitline BLT, complementary bitline BLC, driving voltage line VDD, and ground voltage line VSS may be further positioned at the third wiring layer M2.

Hereinafter, a cell region of a semiconductor device according to some implementations will be described with reference to FIG. 8 to FIG. 10.

FIG. 8 to FIG. 10 are layout diagrams illustrating bit cells of a semiconductor device according to implementations. In the implementations of FIG. 8 to FIG. 10, the layout of one bit cell 120 and a bitline BLT, a complementary bitline BLC, a driving voltage line VDD, and a ground voltage line VSS connected to one bit cell 120 is illustrated for better understanding and convenience of description.

The bitline BLT, the complementary bitline BLC, and the driving voltage line VDD of the implementations of FIG. 8 to FIG. 10 may respectively refer to the bitline BLT portion positioned in the cell region BA, the complementary bitline BLC portion positioned in the cell region BA, and the driving voltage line VDD portion positioned in the cell region BA of the implementations of FIG. 4 and FIG. 5. In other words, the bitline BLT, the complementary bitline BLC, and the driving voltage line VDD of the implementations of FIG. 8 to FIG. 10 may respectively correspond to the first portion B_BLT of the bitline BLT, the fourth portion B_BLC of the complementary bitline BLC, and the seventh portion B_VDD of the driving voltage line VDD of the implementations of FIG. 4 and FIG. 5.

First, referring to FIG. 8, the first pull-down transistor PD1 may be positioned in the first N-well region 1_N-WELL. The source node of the first pull-down transistor PD1 may be connected to the ground voltage line VSS by the first local interconnect LI1, first contact CT1, and first via V1.

The first pass transistor PA1 may be positioned in the first N-well region 1_N-WELL. The source node of the first pass transistor PA1 may be connected to the bitline BLT by the fourth local interconnect LI4, fourth contact CT4, and fourth via V4. Here, the bitline BLT may correspond to the first portion B_BLT of bitline BLT positioned in the cell region BA of the implementations of FIG. 4 and FIG. 5.

The first pull-up transistor PUI may be positioned in the P-well region P-WELL. The source node of the first pull-up transistor PU1 may be connected to the driving voltage line VDD by the second local interconnect LI2, second contact CT2, and second via V2. Here, the driving voltage line VDD may correspond to the seventh portion B_VDD of the driving voltage line VDD positioned in the cell region BA of the implementations of FIG. 4 and FIG. 5.

The second pull-down transistor PD2 may be positioned in a second N-well region 2_N-WELL. The source node of the second pull-down transistor PD2 may be connected to the ground voltage line VSS by the sixth local interconnect LI6, sixth contact CT6, and sixth via V6.

The second pass transistor PA2 may be positioned in the second N-well region 2_N-WELL. The source node of the second pass transistor PA2 may be connected to the complementary bitline BLC by a third local interconnect LI3, third contact CT3, and third via V3. Here, the complementary bitline BLC may correspond to the fourth portion B_BLC of the complementary bitline BLC positioned in the cell region BA of the implementations of FIG. 4 and FIG. 5.

The second pull-up transistor PU2 may be positioned in the P-well region P-WELL. The source node of the second pull-up transistor PU2 may be connected to the driving voltage line VDD by the fifth local interconnect LI5, fifth contact CT5, and fifth via V5.

The first pass transistor PA1 may include fourth gate line G4, and the second pass transistor PA2 may include third gate line G3.

The drain nodes of the first pull-down transistor PD1, the first pass transistor PA1, and the first pull-up transistor PU1 may be connected to the second gate line G2 by the seventh local interconnect LI7 and the seventh contact CT7.

The drain nodes of the second pull-down transistor PD2, the second pass transistor PA2, and the second pull-up transistor PU2 may be connected to the first gate line G1 by the eighth local interconnect LI8 and the eighth contact CT8.

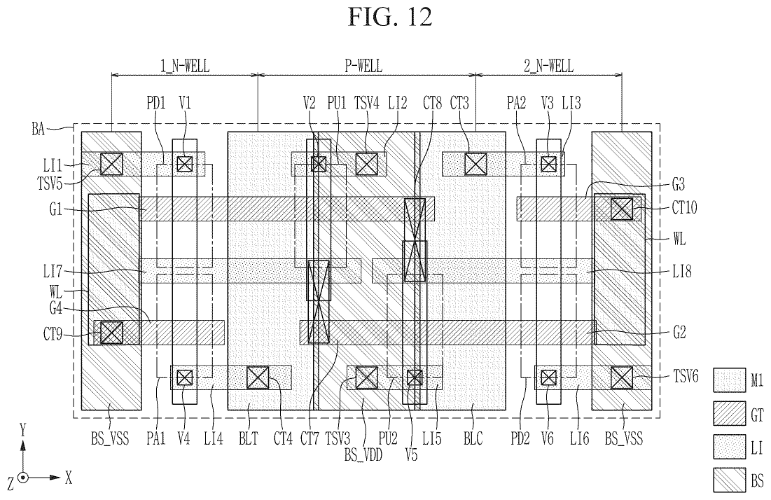

Meanwhile, the driving voltage line VDD, bitline BLT, complementary bitline BLC, and ground voltage line VSS may be positioned on the top of the substrate where the transistors are positioned. For example, the driving voltage line VDD, bitline BLT, complementary bitline BLC, and ground voltage line VSS may be positioned at the first wiring layer (M1 in FIG. 7) on the device layer (TL in FIG. 7) where the transistors are positioned. At this time, the driving voltage line VDD, bitline BLT, complementary bitline BLC, and ground voltage line VSS may be positioned at the same layer. Additionally, the driving voltage line VDD, bitline BLT, and complementary bitline BLC may be positioned only at the first wiring layer M1, and the ground voltage line VSS may be positioned at the first wiring layer M1 and the third wiring layer M2. However, not limited thereto, the driving voltage line VDD and the ground voltage line VSS may be positioned under the substrate. Further explanation of this will be described later with reference to FIG. 12.

Referring to FIG. 9, the ground voltage line VSS may further include a sub-ground voltage line VSS. The sub-ground voltage line VSS may be positioned on the ground voltage line VSS. For example, the ground voltage line VSS may be positioned at the first wiring layer M1, and the sub-ground voltage line VSS may be positioned at the third wiring layer M2 on the first wiring layer M1. The sub-ground voltage line VSS may be electrically connected to the ground voltage line VSS through the ground voltage contact (CT_VSS). In some implementations, the sub-ground voltage line VSS may have a mesh shape.

The bitline BLT and the complementary bitline BLC may be positioned to be spaced apart from the driving voltage line VDD in the first direction (X direction). The ground voltage line VSS may be positioned to be spaced apart from the bitline BLT and the complementary bitline BLC in the first direction (X direction).

The widths of the ground voltage line VSS, bitline BLT, complementary bitline BLC, and driving voltage line VDD in the first direction (X direction) may be different. For example, the width of a bitline BLT along the first direction (X direction) may be substantially the same as the width of a complementary bitline BLC along the first direction (X direction). Additionally, the width of the bitline BLT along the first direction (X direction) and the width of the complementary bitline BLC along the first direction (X direction) may be greater than or equal to the width of the driving voltage line VDD and the ground voltage line VSS along the first direction (X direction), but implementations are not limited thereto. Accordingly, the resistance of the bitline BLT and the complementary bitline BLC can be reduced, and the reliability of the signal applied to the bit cell 120 from the peripheral circuit through the bitline BLT and the complementary bitline BLC may be improved.

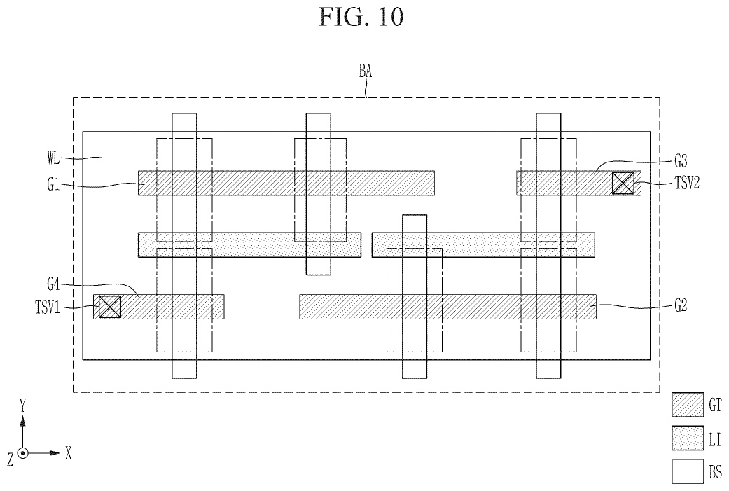

Referring to FIG. 10, a semiconductor device according to some implementations may further include a gate signal line WL.

The gate signal line WL may be extended in the first direction (X direction) but is not limited thereto. In implementations, the gate signal line WL may be positioned at a second wiring layer BS positioned below the substrate (SUB in FIG. 7). The gate signal line WL may be connected to the fourth gate line G4 through the first penetrating contact TSV1 extending through the substrate (SUB in FIG. 7). Accordingly, the gate signal line WL may be connected to the gate node of the first pass transistor PA1 through the first penetrating contact TSV1. Also, the gate signal line WL may be connected to the third gate line G3 through a second penetrating contact TSV2 extending through the substrate (SUB in FIG. 7). Accordingly, the gate signal line WL may be connected to the gate node of the second pass transistor PA2 through the second penetrating contact TSV2.

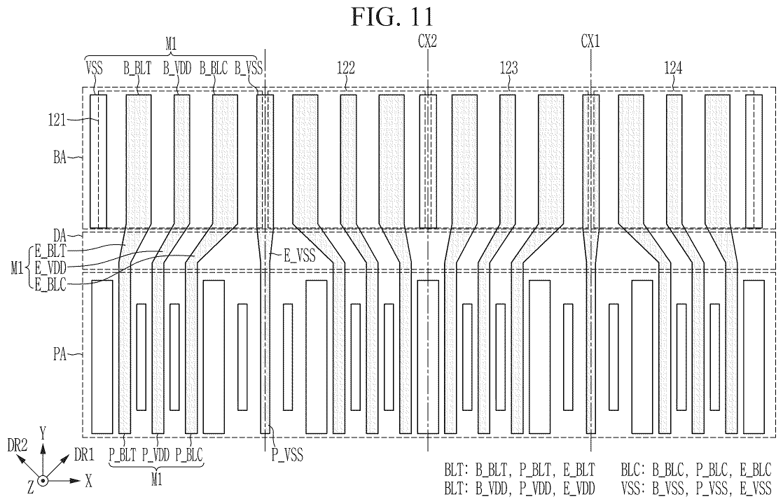

Hereinafter, a semiconductor device according to some implementations will be described with reference to FIG. 11.

FIG. 11 is a layout diagram illustrating a bit cell region, a dummy region, and a peripheral circuit region of a semiconductor device according to some implementations.

In FIG. 11, only the arrangement and shape of the cell region BA, peripheral circuit region PA, dummy region DA, bitline BLT, complementary bitline BLC, and driving voltage line VDD which connect between plurality of bit cells 120, plurality of standard cells SC1 and SC2, and a ground voltage line VSS are shown for better understanding and convenience of description. Since many parts of the implementations of FIG. 11 are the same as the implementations of FIG. 4 and FIG. 5, the description will focus on differences from the implementations of FIG. 4 and FIG. 5.

Referring to FIG. 11, at least one of a plurality of ground voltage lines (VSS) of a semiconductor device according to some implementations may be extended from a cell region BA through a dummy region DA to a peripheral circuit region PA. The ground voltage line VSS may be positioned at the same layer across the cell region BA, dummy region DA, and peripheral circuit region PA. For example, the ground voltage line VSS may be positioned at the first wiring layer (M1 in FIG. 7) on the plurality of bit cells 120 across the cell region BA, the dummy region DA, and the peripheral circuit region PA, but the positions are not limited thereto. In implementations, the ground voltage line VSS may be extended approximately in the second direction (Y direction). The ground voltage line VSS may be positioned apart from the bitline BLT, complementary bitline BLC, and driving voltage line VDD along the first direction (X direction).

Referring to FIG. 5, the ground voltage line VSS may include a first line portion B_VSS positioned in the cell region BA, a second line portion P_VSS positioned in the peripheral circuit region PA, and a third line portion E_VSS connecting between the first line portion B_VSS and the second line portion P_VSS.

In implementations, the first line portion B_VSS to the third line portion E_VSS of the ground voltage line VSS may be positioned at the same layer. For example, the first line portion B_VSS to the third line portion E_VSS may be positioned at the first wiring layer (M1 of FIG. 7) positioned on a plurality of bit cells 120. In implementations, the first line portion B_VSS to the third line portion E_VSS may be formed integrally. The first line portion B_VSS and the third line portion E_VSS may be integrally formed in the same process.

The first line portion B_VSS to the third line portion E_VSS may be extended in the second direction (Y direction). However, implementations are not limited thereto, and the first line portion B_VSS and the second line portion P_VSS may be extended in the second direction (Y direction), and the third line portion E_VSS may be extended in the first diagonal direction DR1 or in the second diagonal direction DR2.

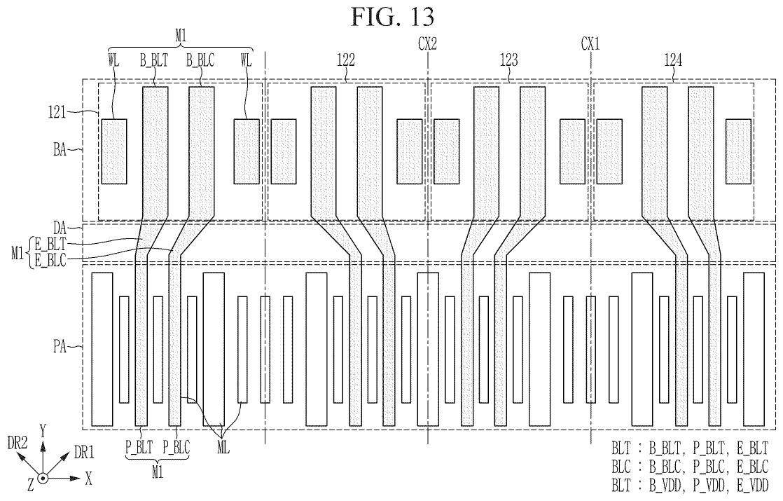

Hereinafter, a bit cell of a semiconductor device according to some embodiment will be described with reference to FIG. 12 and FIG. 13.

FIG. 12 is a layout diagram illustrating a bit cell of a semiconductor device according to some implementations. FIG. 13 is a layout diagram illustrating a bit cell region, a dummy region, and a peripheral circuit region of a semiconductor device according to some implementations.

FIG. 13 is a layout diagram illustrating a bitline BLT, a complementary bitline BLC and a gate signal line WL positioned in a cell region BA, a peripheral circuit region PA, a dummy region DA according to implementations of FIG. 12. In FIG. 13, only the bitline BLT, complementary bitline BLC, driving voltage line VDD, and gate signal line WL are shown for better understanding and ease of description. Since many parts of the implementations of FIG. 12 and FIG. 13 are the same as the implementations of FIG. 8 to FIG. 10, the description will focus on differences from the implementations of FIG. 8 to FIG. 10.

First, referring to FIG. 12, the driving voltage line BS_VDD and the ground voltage line BS_VSS of a semiconductor device according to some implementations may be positioned at layers different from the bitline BLT and the complementary bitline BLC.

For example, the driving voltage line BS_VDD and the ground voltage line BS_VSS may be positioned at the second wiring layer (BS in FIG. 7) positioned on the bottom surface of the substrate (SUB in FIG. 7). At this time, the bitline BLT and complementary bitline BLC may be positioned at the first wiring layer (M1 in FIG. 7) positioned on the substrate (SUB in FIG. 7). The driving voltage line BS_VDD and ground voltage line BS_VSS may be extended in the second direction (Y direction). The driving voltage line BS_VDD and the ground voltage line BS_VSS may be spaced apart from each other along the first direction (X direction). In some implementations, the driving voltage line BS_VDD may overlap the bitline BLT and/or complementary bitline BLC in the third direction (Z direction), but are not limited thereto.

In implementations, the driving voltage line BS_VDD may be connected to the source node of the first pull-up transistor PU1 and the source node of the second pull-up transistor PU2. For example, as illustrated in FIG. 12, the driving voltage line BS_VDD may be connected to the source node of the first pull-up transistor PU1 through the fourth penetrating contact TSV4, the second local interconnect LI2, and the second via V2. Also, the driving voltage line BS_VDD may be connected to the source node of the second pull-up transistor PU2 through the third penetrating contact TSV3, the fifth local interconnect LI5, and the fifth via V5. Here, the third penetrating contact TSV3 and the fourth penetrating contact TSV4 may be penetrating vias that penetrate the substrate (SUB in FIG. 7). However, the contacts and vias are not limited thereto. As another example, the driving voltage line BS_VDD may be connected to the source node of the first pull-up transistor PU1 and the source node of the second pull-up transistor PU2 only through a penetrating via extending through the substrate (SUB in FIG. 7).

Additionally, the ground voltage line BS_VSS may be connected to the source node of the first pull-down transistor PD1 through the fifth penetrating contact TSV5, the first local interconnect LI1, and the first via V1. Additionally, the ground voltage line BS_VSS may be connected to the source node of the second pull-down transistor PD2 through the sixth penetrating contact TSV6, the sixth local interconnect LI6, and the fifth via V6. Here, the fifth penetrating contact TSV5 and the sixth penetrating contact TSV6 may be penetrating vias that extend through the substrate (SUB in FIG. 7). However, the contacts and vias not limited thereto. As another example, the ground voltage line BS_VSS may also be connected to the source node of the first pull-down transistor PD1 and the source node of the second pull-down transistor PD2 only through a penetrating via extending through the substrate (SUB in FIG. 7).

In a semiconductor device according to some implementations, the gate signal line WL may be positioned at the same layer as the bitline BLT and the complementary bitline BLC. [symbol] In a semiconductor device, according to some implementations, for example, the gate signal line WL may be positioned at the first wiring layer M1. The gate signal line WL may be positioned apart from the bitline BLT and the complementary bitline BLC along the first direction (X direction). The gate signal line WL may be positioned at both sides of a pair of a bitline BLT and a complementary bitline BLC along the first direction (X direction). In some implementations, the gate signal line WL may be connected to the fourth gate line G4 via the ninth contact CT9 and may be connected to the third gate line G3 via the tenth contact CT10. In some implementations, the gate signal line WL may overlap the ground voltage line BS_VSS in the third direction (Z direction), but is not limited thereto.

Referring to FIG. 13, in a semiconductor device according to some implementations, the bitline BLT and the complementary bitline BLC may be positioned at the first wiring layer M1, and the driving voltage line BS_VDD and the ground voltage line BS_VSS may be positioned at the second wiring layer BS. Even in this case, as the implementations of FIG. 4 and FIG. 5, the bitline BLT and the complementary bitline BLC may be formed integrally in the cell region BA, the dummy region DA, and the peripheral circuit region PA. Additionally, the driving voltage line BS_VDD and the ground voltage line BS_VSS may be formed integrally in the cell region BA, the dummy region DA, and the peripheral circuit region PA, but are not limited thereto.

In a semiconductor devices according to some implementations, the bitline BLT and the complementary bitline BLC may be positioned at the first wiring layer M1, and a driving voltage line BS_VDD and a ground voltage line BS_VSS positioned at the second wiring layer BS. Accordingly, the space for forming bitlines BLT and complementary bitlines BLC at the first wiring layer M1 can relatively increase, and the width of bitlines BLT and complementary bitlines BLC in the first direction (X direction) can be easily increased. Accordingly, the resistance of bitline BLT and complementary bitline BLC may be reduced. Therefore, the reliability of the signal applied to bit cell 120 from the peripheral circuit through the bitline BLT and complementary bitline BLC may be improved, and the reliability of the semiconductor device can be improved.

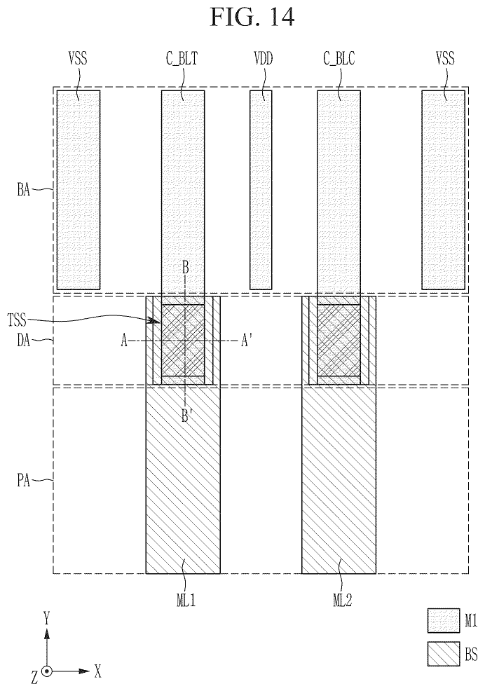

Hereinafter, the bitlines and the complementary bitlines of a semiconductor device according to some implementations will be described with reference to FIG. 14 to FIG. 17.

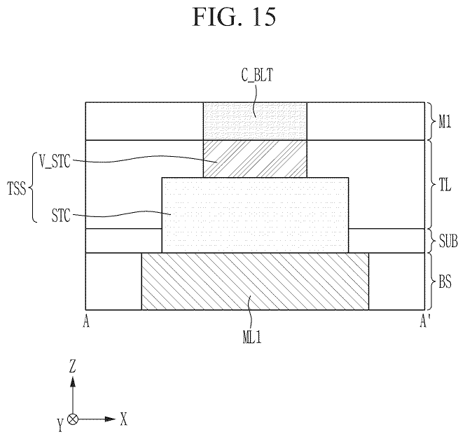

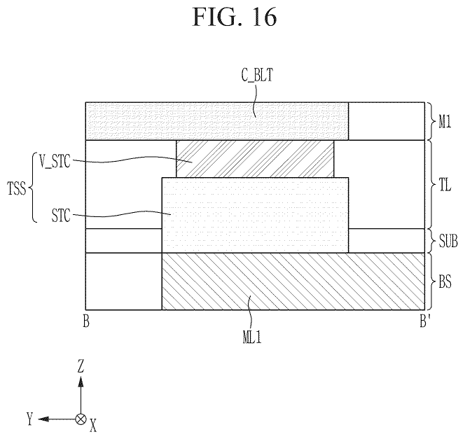

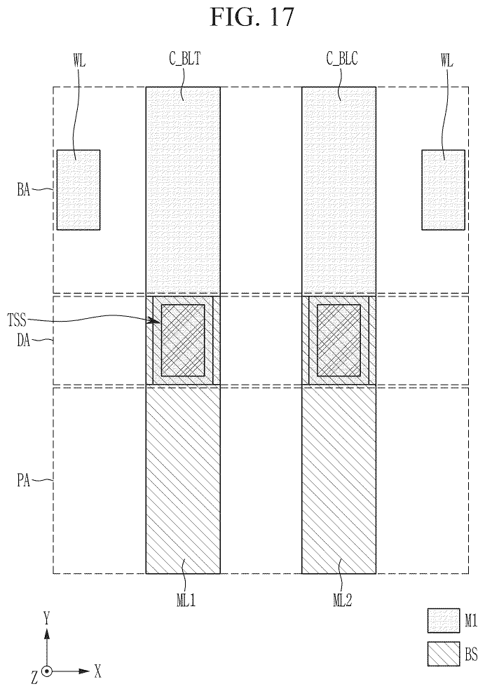

FIG. 14 is a layout diagram illustrating a bit cell region, a dummy region, and a peripheral circuit region of a semiconductor device according to some implementations. FIG. 15 is a cross-sectional view along the A-A′ line in FIG. 14. FIG. 16 is a cross-sectional view along the B-B′ line in FIG. 14. FIG. 17 is a layout diagram illustrating a bit cell region, a dummy region, and a peripheral circuit region of a semiconductor device according to some implementations.

FIG. 14 to FIG. 17 show only the wirings positioned at the first wiring layer M1 in the cell region BA and the wirings positioned at the second wiring layer BS in the peripheral circuit region PA for better understanding and convenience of description. Since many parts of the implementations of FIG. 14 to FIG. 17 are the same as the implementations of FIG. 4 to FIG. 10, the description will focus on differences from the implementations of FIG. 4 to FIG. 10.

Referring to FIG. 14 to FIG. 17, a semiconductor device according to some implementations may include a cell bitline C_BLT and a complementary cell bitline C_BLC positioned in a cell region BA, a cell bitline extension wiring ML1 and a complementary cell bitline extension wiring ML2 positioned in a peripheral circuit region PA, and a penetrating via structure TSS connecting between the cell bitline C_BLT and the cell bitline extension wiring ML1 and between the complementary cell bitline C_BLC and the complementary cell bitline extension wiring ML2.

The cell bitline C_BLT and complementary cell bitline C_BLC are positioned in the cell region BA and the dummy region DA, but may not be positioned in the peripheral circuit region PA. A cell bitline C_BLT and a complementary cell bitline C_BLC may be positioned on a plurality of bit cells 120. For example, the cell bitline C_BLT and complementary cell bitline C_BLC may be positioned at the first wiring layer M1 positioned above the gate lines (G1-G4 in FIG. 8). In some implementations, the cell bitline C_BLT may correspond to the first portion B_BLT of the bitline BLT of the implementations of FIG. 4 and FIG. 5, and the complementary cell bitline C_BLC may correspond to the fourth portion B_BLC of the complementary bitline BLC of the implementations of FIG. 4 and FIG. 5.

In some implementations, the driving voltage line VDD, the ground voltage line VSS, and the gate signal line WL may be positioned at the same layer as the cell bitline C_BLT and the complementary cell bitline C_BLC or in different layers. For example, as illustrated in FIG. 16, the driving voltage line VDD and the ground voltage line VSS may be positioned at the first wiring layer M1 as same as the cell bitline C_BLT and the complementary cell bitline C_BLC. As another example, as illustrated in FIG. 17, the gate signal line WL may be positioned at the first wiring layer M1 as same as the cell bitline C_BLT and the complementary cell bitline C_BLC.

In the peripheral circuit region PA, the cell bitline extension wiring ML1 and the complementary cell bitline extension wiring ML2 may be positioned. The cell bitline extension wiring ML1 and the complementary cell bitline extension wiring ML2 may be positioned in the peripheral circuit region PA and the dummy region DA, but may not be positioned in the cell region BA. The cell bitline extension wiring ML1 and the complementary cell bitline extension wiring ML2 may be positioned at layers different from the cell bitline C_BLT and the complementary cell bitline C_BLC. For example, the cell bitline extension wiring ML1 and the complementary cell bitline extension wiring ML2 may be positioned at the second wiring layer BS. At least a portion of the cell bitline extension wiring ML1 and the complementary cell bitline extension wiring ML2 may overlap the cell bitline C_BLT and the complementary cell bitline C_BLC in the third direction (Z direction).

In some implementations, the penetrating via structure TSS may be positioned in a dummy region DA. That is, the penetrating via structure TSS may be positioned between the cell region BA and the peripheral circuit region PA. A penetrating via structure TSS may be extended in the third direction (Z direction) to connect between the cell bitline C_BLT and the cell bitline extension wiring ML1, and between the complementary cell bitline C_BLC and the complementary cell bitline extension wiring ML2.

Specifically, as illustrated in FIG. 15 and FIG. 16, the penetrating via structure TSS may include a first penetrating via STC penetrating at least a portion of the substrate SUB and the device layer TL, and a second penetrating via V_STC extending through the remaining portion of the device layer TL.

The first penetrating via STC may be extended in the third direction (Z direction). The first penetrating via STC may penetrate the substrate SUB to be connected to the cell bitline extension wiring ML1 and the complementary cell bitline extension wiring ML2 positioned on the second wiring layer BS. The bottom surface of the first penetrating via STC may contact the cell bitline extension wiring ML1 and the complementary cell bitline extension wiring ML2. At this time, the width of the first penetrating via STC along the first direction (X direction) may be smaller than or equal to the width of the cell bitline extension wiring ML1 and the complementary cell bitline extension wiring ML2 along the first direction (X direction). The second penetrating via V_STC may be positioned on top of the first penetrating via STC. A second penetrating via V_STC may connect between the first penetrating via STC and the cell bitline C_BLT. The width of the first penetrating via STC along the first direction (X direction) may be smaller than the width of the second penetrating via V_STC along the first direction (X direction). Additionally, the width of the cell bitline C_BLT along the first direction (X direction) may be smaller than or equal to the width of the first penetrating via STC along the first direction (X direction).

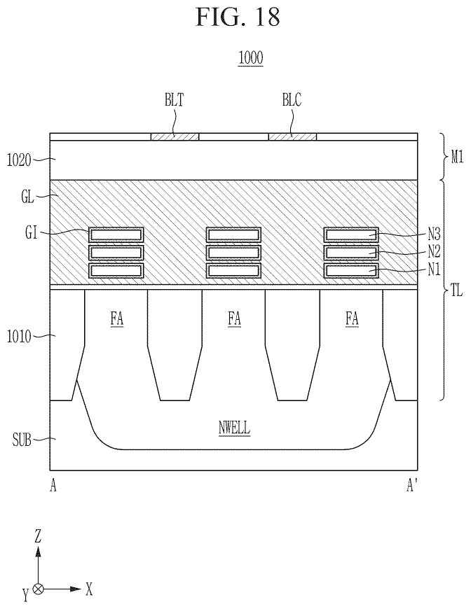

Hereinafter, exemplary shapes of the standard cell according to some implementations will be described with reference to FIG. 18.

FIG. 18 is a cross-sectional view illustrating a standard cell of a semiconductor device according to implementations. FIG. 18 illustrates an example of nano sheets being formed as an active pattern in an active region. However, the semiconductor device according to the present disclosure is not limited to this.

Referring to FIG. 18, in some implementations, a plurality of active regions FA extend in a third direction (Z direction) may be positioned on a substrate SUB, and a nano sheet stacking structure in which a plurality of nano sheets N1, N2, and N3 are stacked may be positioned on top of each of the plurality of active regions FA.

The plurality of active regions FA may be formed within the N-well region NWELL of the substrate SUB. A trench 1010 defining an active region FA may be positioned between the plurality of active regions FA. The plurality of active regions FA may be separated from each other by trench 1010. In some implementations, an insulating material may be positioned within the trench 1010.

In implementations, the plurality of nano sheets N1, N2, and N3 may be positioned on each of the plurality of active regions FA. The plurality of nano sheets N1, N2, and N3 may be arranged spaced apart from a plurality of active region FA in the third direction (Z direction). Each of the nano sheets N1, N2, and N3 may be extended in a horizontal direction on the plurality of active regions FA. Each nano sheet N1, N2, and N3 may be stacked one by one on the plurality of active regions FA and may function as a channel of the transistor. For example, a P-type transistor may be formed when a plurality of nano sheets N1, N2, and N3 are doped with N-type impurities, and an N-type transistor may be formed when P-type impurities are doped. Meanwhile, FIG. 18 illustrates that three nano sheets N1, N2, and N3 form the nano sheet stacking structure, but implementations are not limited thereto. In addition, although the plurality of nano sheets N1, N2, and N3 have a planar shape that is approximately a quadrangle shape, implementations are not limited thereto. Each of the plurality of nano sheets N1, N2, and N3 may have various planar shapes depending on the planar shape of the active region FA and the planar shape of the gate structures GI, GL. Nano sheets N1, N2, and N3 may be composed of silicon (Si), germanium (Ge), or silicon-germanium (SiGe), and may also be composed of InGaAs, InAs, GaSb, InSb, or a combination thereof.

The gate structures (GI, GL) may surround at least some of the nano sheets N1, N2, and N3. For example, the gate structures GI, GL may include a gate line GL surrounding nano-sheets N1, N2, and N3 and a gate insulating layer GI positioned between the nano-sheets N1, N2, and N3 and the gate line GL. An interlayer insulating layer 1020 may be positioned on the gate line GL, and the gate line GL and wirings of the first wiring layer may be connected through a gate contact and a gate via extending through the interlayer insulating layer 1020. Additionally, a bitline BLT and a complementary bitline BLC positioned at the first wiring layer M1 may be connected to an end of the transistor through a via extending through the interlayer insulating layer 1020.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the present disclosure have been described in detail above, the scope of the present disclosure is not limited thereto, and various modifications and improvements can be made by those skilled in the art using the basic concept of the present disclosure defined in the following claims, and they fall within the scope of the present disclosure.

### Description of Symbols

BA: cell region
PA: peripheral circuit region
120: bit cell
BLT: bitline
B_BLT: first portion
P_BLT: second portion
E_BLT: third portion
BLC: complementary bitline
VDD: driving voltage line
VSS: ground voltage line

What is claimed is:

1. A semiconductor device comprising:
a cell region in which a plurality of bit cells are arranged;
a peripheral circuit region which is positioned at a side of the cell region, and where a circuit configured to control the plurality of bit cells is positioned;
a bitline extending in a first direction in the cell region and the peripheral circuit region; and
a complementary bitline spaced apart from the bitline in a second direction intersecting the first direction in the cell region and the peripheral circuit region,
wherein each of the plurality of bit cells comprises
a first pull-up transistor pulling up a first storage node,
a second pull-up transistor pulling up a second storage node,
a first pass transistor connecting the first storage node to the bitline,
a second pass transistor connecting the second storage node to the complementary bitline,
a first pull-down transistor pulling down the first storage node, and
a second pull-down transistor pulling down the second storage node; and
wherein the bitline comprises
a first portion positioned in the cell region and extending in the first direction,
a second portion positioned in the peripheral circuit region and extending in the first direction, and
a third portion connecting the first portion and the second portion,
wherein the first portion, the second portion, and the third portion are formed integrally and positioned at the same layer.

2. The semiconductor device of claim 1,
wherein the third portion extends in a first diagonal direction intersecting the first direction and the second direction.

3. The semiconductor device of claim 1,
wherein a width of the first portion along the second direction is greater than or equal to a width of the second portion along the second direction.

4. The semiconductor device of claim 3,
wherein a width of the third portion along the second direction gradually decreases as a distance from the first portion increases.

5. The semiconductor device of claim 1,
wherein the bitline has a bent portion between the first portion and the third portion and between the second portion and the third portion.

6. The semiconductor device of claim 1,
wherein the bitline and the complementary bitline are positioned on the plurality of bit cells.

7. The semiconductor device of claim 1, wherein
the complementary bitline comprises:
a fourth portion positioned in the cell region and extending in the first direction;
a fifth portion positioned in the peripheral circuit region and extending in the first direction; and
a sixth portion connecting the fourth portion and the fifth portion, and wherein
the fourth portion to the sixth portion are formed integrally and positioned at the same layer.

8. The semiconductor device of claim 7,
wherein the fourth portion extends in a first diagonal direction intersecting the first direction and the second direction.

9. The semiconductor device of claim 1, wherein
the plurality of bit cells includes a first bit cell and a second bit cell adjacent to the first bit cell in the second direction,
the bitline comprises a first bitline positioned on the first bit cell, and a second bitline positioned on the second bit cell, and
wherein the first bitline and the second bitline have shapes symmetrical to each other with respect to a boundary between the first bit cell and the second bit cell.

10. The semiconductor device of claim 9, wherein
the complementary bitline comprises a first complementary bitline positioned on the first bit cell, and a second complementary bitline positioned on the second bit cell, and
wherein the first complementary bitline and the second complementary bitline have shapes symmetrical to each other with respect to a boundary between the first bit cell and the second bit cell.

11. The semiconductor device of claim 10, wherein
the first complementary bitline is positioned between the first bitline and the second bitline, and
the second complementary bitline is positioned between the second bitline and the first complementary bitline.

12. The semiconductor device of claim 1, further comprising
a driving voltage line extending in the first direction and spaced apart from the bitline in the second direction, in the cell region and the peripheral circuit region,
wherein the driving voltage line comprises:
a seventh portion positioned in the cell region and extending in the first direction;
an eighth portion positioned in the peripheral circuit region and extending in the first direction; and
a ninth portion connecting the seventh portion and the eighth portion, and wherein
the seventh portion to the ninth portion are formed integrally and positioned at the same layer.

13. The semiconductor device of claim 12,
wherein the driving voltage line, the bitline, and the complementary bitline are positioned at the same layer.

14. The semiconductor device of claim 12, wherein
the bitline and the complementary bitline are positioned at the same layer on the plurality of bit cells, and
the driving voltage line is positioned below the plurality of bit cells.

15. The semiconductor device of claim 12, further comprising
a gate signal line in the cell region and connected to a gate of the first pass transistor and to a gate of the second pass transistor,
wherein the gate signal line, the bitline, and the complementary bitline are positioned at the same layer on the plurality of bit cells.

16. A semiconductor device comprising:
a cell region in which a plurality of bit cells are arranged;
a peripheral circuit region which is positioned at a side of the cell region, and where a circuit configured to control the plurality of bit cells is positioned; and
a penetrating via structure positioned between the cell region and the peripheral circuit region,
wherein the cell region comprises
gate lines positioned on a substrate,
a cell bitline extending in a first direction and positioned on a first wiring layer on the gate lines, and
a complementary cell bitline positioned at the first wiring layer and spaced apart from the cell bitline in a second direction intersecting the first direction,
each of the plurality of bit cells comprises
a first pull-up transistor pulling up a first storage node,
a second pull-up transistor pulling up a second storage node,
a first pass transistor connecting the first storage node to the cell bitline,
a second pass transistor connecting the second storage node to the complementary cell bitline,
a first pull-down transistor pulling down the first storage node, and
a second pull-down transistor pulling down the second storage node,
the peripheral circuit region comprises
a cell bitline extension wiring extending in the first direction and positioned at a second wiring layer below the substrate, and
a complementary cell bitline extension wiring positioned at the second wiring layer, extending in the first direction, and spaced apart from the cell bitline extension wiring in the second direction, and
the penetrating via structure connects between the cell bitline and the cell bitline extension wiring.

17. The semiconductor device of claim 16, wherein
the penetrating via structure comprises:
a first penetrating via positioned on the second wiring layer; and
a second penetrating via positioned on the first penetrating via, and
a width of the second penetrating via along the first direction is smaller than a width of the first penetrating via along the first direction.

18. The semiconductor device of claim 17, wherein
a width of the first penetrating via along the first direction is less than or equal to a width of the cell bitline extension wiring along the first direction, and
a width of the second penetrating via along the first direction is less than or equal to a width of the cell bitline along the first direction.

19. The semiconductor device of claim 16, wherein
a width of the cell bitline along the second direction is less than or equal to a width of the cell bitline extension wiring along the second direction, and
a width of the complementary cell bitline along the second direction is less than or equal to a width of the complementary cell bitline extension wiring along the second direction.

20. A semiconductor device comprising:
a cell region in which a plurality of bit cells are arranged;
a peripheral circuit region which is positioned at a side of the cell region, and where a circuit configured to control the plurality of bit cells is positioned;
a driving voltage line extending in a first direction in the cell region;
a bitline in the cell region and the peripheral circuit region, wherein the bit line extends in the first direction and is spaced apart from the driving voltage line in a second direction intersecting the first direction; and
a complementary bitline spaced apart from the bitline in the second direction in the cell region and the peripheral circuit region,
wherein
the bitline comprises
a first portion positioned in the cell region and extending in the first direction,
a second portion positioned in the peripheral circuit region and extending in the first direction, and
a third portion connecting the first portion and the second portion,
the first portion to the third portion being formed integrally and positioned at the same layer, and
a width of the first portion along the second direction is greater than or equal to a width of the second portion along the second direction.
